(19) United States
(12) Patent Application Publication
(10) Pub. No.: US 2011/0041917 A1
(43) Pub. Date: Feb. 24, 2011

(54) Doped Transparent Conductive Oxide

(75) Inventors: Douglas Dauson, Perrysburg, OH (US); Scott Mills, Perrysburg, OH (US); Boil Pashmakov, Troy, MI (US); Dale Roberts, Temperance, MI (US); Zhibo Zhao, Novi, MI (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/860,115

(22) Filed: Aug. 20, 2010

Related U.S. Application Data
(60) Provisional application No. 61/236,431, filed on Aug. 24, 2009.

(51) Int. Cl. H01L 31/04; H01L 31/0352

(52) U.S. Cl. 136/260; 438/94; 136/252; 136/262; 257/E31.032

(57) ABSTRACT

A solar cell with a doped transparent conductive oxide layer is disclosed. The doped transparent conductive oxide layer can improve the efficiency of CdTe-based or other kinds of solar cells.

### CLAIM OF PRIORITY

This application claims priority to U.S. Provisional Patent Application No. 61/236,431, filed on Aug. 24, 2009, which is incorporated by reference in its entirety.

### TECHNICAL FIELD

This invention relates to a solar cell with a doped transparent conductive oxide layer.

### BACKGROUND

Photovoltaic devices can use transparent thin films that are also conductors of electrical charge. The conductive thin films can include transparent conductive layers that contain one or more transparent conductive oxide (TCO) layers. The TCO layers can allow light to pass through a semiconductor window layer to the active light absorbing material and also serve as an ohmic contact to transport photogenerated charge carriers away from the light absorbing material.

### DESCRIPTION OF DRAWINGS

FIG. 1 is a schematic of a photovoltaic device having a transparent conductive oxide layer, multiple semiconductor layers, and a metal back contact.

FIG. 2 is a schematic of a photovoltaic substrate.

FIG. 3 is a schematic of a photovoltaic device having a transparent conductive oxide stack, multiple semiconductor layers, and a metal back contact.

FIG. 4 is a process flow chart of making a doped sputter target.

FIG. 5 is a schematic showing the sputtering deposition process of TCO stack.

### DETAILED DESCRIPTION

For thin film solar cells, the transparent conductive oxide (TCO) material used as front contact can influence device performance. TCO layers with high electrical conductivity can be desirable. The TCO layer's thickness can be increased to lower the sheet resistance. In practice, a thick TCO layer can result in cost increase, peeling and adhesion problems, and manufacturing difficulties. A thicker TCO layer can also undesirably increase the optical absorptions. Methods of making doped TCO layers are developed with low resistivity and high mobility without increasing their thickness. Furthermore, the deposited doped TCO layers can transform to their conducting/transparent state during the following semiconductor layers deposition process, thus no additional annealing process is needed.

A photovoltaic device can include a transparent conductive oxide layer adjacent to a substrate and layers of semiconductor material. The layers of semiconductor material can include a bi-layer, which may include an n-type semiconductor window layer, and a p-type semiconductor absorber layer. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current, which combined with the resulting voltage from the electric field, creates power. The result is the conversion of photon energy into electric power. To preserve and enhance device performance, numerous layers can be positioned above the substrate in addition to the semiconductor window and absorber layers. Photovoltaic devices can be formed on optically transparent substrates, such as glass. Because glass is not conductive, a transparent conductive oxide (TCO) layer is typically deposited between the substrate and the semiconductor bi-layer. Transparent conductive oxides function well in this capacity, as they exhibit high optical transmission and low electrical sheet resistance.

In one aspect, a photovoltaic substrate can include a substrate, a barrier layer adjacent to the substrate, a transparent conductive oxide layer adjacent to the barrier layer, wherein the transparent conductive oxide layer can be doped with a dopant to achieve lower resistivity, and a buffer layer adjacent to the transparent conductive oxide layer. The transparent conductive oxide layer can include cadmium oxide. The transparent conductive oxide layer can include indium oxide. The transparent conductive oxide layer can include cadmium indium oxide. The dopant can include titanium, gallium, tin, yttrium, scandium, niobium, or molybdenum. The buffer layer can include tin oxide. The buffer layer can include zinc oxide. The buffer layer can include zinc tin oxide. The transparent conductive oxide layer can be doped with a dopant to control the band gap. The substrate can include glass. The photovoltaic substrate can further include a semiconductor bi-layer adjacent to the transparent conductive oxide layer, wherein the semiconductor bi-layer can include a semiconductor absorber layer and a semiconductor window layer. The barrier layer can include silicon oxide.

In one aspect, a photovoltaic device can include a substrate, a barrier layer adjacent to the substrate, a transparent conductive oxide layer adjacent to the barrier layer, wherein the transparent conductive oxide layer can be doped with a dopant to achieve lower resistivity, a buffer layer adjacent to the transparent conductive oxide layer, and a semiconductor bi-layer adjacent to the transparent conductive oxide layer, wherein the semiconductor bi-layer can include a semiconductor absorber layer and a semiconductor window layer. The transparent conductive oxide layer can include cadmium oxide. The transparent conductive oxide layer can include indium oxide. The transparent conductive oxide layer can include the cadmium indium oxide. The dopant can include titanium, gallium, tin, yttrium, scandium, niobium, or molybdenum. The buffer layer can include tin oxide. The buffer layer can include zinc oxide. The buffer layer can include zinc tin oxide. The transparent conductive oxide layer can be doped with a dopant to control the band gap. The substrate can include glass. The semiconductor absorber layer can include cadmium telluride. The semiconductor window layer can include cadmium sulfide. The barrier layer can include silicon oxide. The thicknesses of the barrier layer can be in the range of about 250 angstrom to about 2500 angstrom. The thicknesses of the transparent conductive oxide layer can be in the range of about 1000 angstrom to about 4000 angstrom. The thicknesses of the buffer layer can be in the range of about 250 angstrom to about 2500 angstrom.

In one aspect, a method of manufacturing a photovoltaic substrate can include the steps of depositing a barrier layer adjacent to a substrate, depositing a transparent conductive oxide layer adjacent to the barrier layer, wherein the transparent conductive oxide layer can be doped with a dopant to achieve lower resistivity, depositing a buffer layer adjacent to the transparent conductive oxide layer, and depositing a semiconductor bi-layer adjacent to the buffer layer, wherein the semiconductor bi-layer can include a semiconductor absorber layer and a semiconductor window layer. The transparent conductive oxide layer can include cadmium oxide. The transparent conductive oxide layer can include indium oxide. The transparent conductive oxide layer can include the cadmium indium oxide. The dopant can include titanium, gallium, tin, yttrium, scandium, niobium, or molybdenum. The buffer layer can include tin oxide. The buffer layer can include zinc oxide. The buffer layer can include zinc tin oxide. The transparent conductive oxide layer can be doped with a dopant to control the band gap. The substrate can include glass. The semiconductor absorber layer can include cadmium telluride. The semiconductor window layer can include cadmium sulfide. The barrier layer can include silicon oxide. The barrier layer can be deposited by sputtering. The barrier layer can be deposited by reactive sputtering.

The transparent conductive oxide layer can be deposited by sputtering. The transparent conductive oxide layer can be deposited by reactive sputtering from a doped target. The buffer layer can be deposited by sputtering. The buffer layer can be deposited by reactive sputtering. The method can further include annealing the transparent conductive oxide layer. The thicknesses of the barrier layer can be in the range of about 250 angstrom to about 2500 angstrom. The thicknesses of the transparent conductive oxide layer can be in the range of about 1000 angstrom to about 4000 angstrom. The thicknesses of the buffer layer can be in the range of about 250 angstrom to about 2500 angstrom.

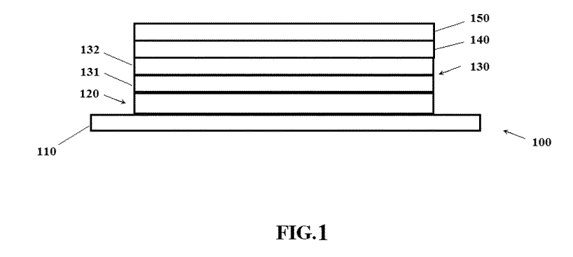

Referring to FIG. 1, photovoltaic device 100 can include doped transparent conductive oxide stack 120 deposited adjacent to substrate 110. Substrate 110 can include a glass, such as soda-lime glass or an improved soda-lime glass with reduced iron content. Transparent conductive oxide stack 120 can be deposited on substrate 110 by sputtering, chemical vapor deposition, or any other suitable deposition method. In certain embodiments, transparent conductive oxide stack 120 can be deposited by reactive sputtering with O₂/Ar gas flow. Transparent conductive oxide layer in the stack 120 can include cadmium oxide and indium oxide (CdO:(In₂O₃)ₓ), wherein x can be in the range of about 0.05 to about 0.5. Transparent conductive oxide layer in the stack 120 can also include any suitable transparent conductive oxide material, including a cadmium stannate or a tin-doped indium oxide. The thickness of transparent conductive oxide layer in stack 120 can be in the range of about 1000 angstrom to about 4000 angstrom. A semiconductor bi-layer 130 can be formed or deposited adjacent to transparent conductive oxide layer stack 120 which can be annealed. Semiconductor bi-layer 130 can include semiconductor window layer 131 and semiconductor absorber layer 132. Semiconductor window layer 131 of semiconductor bi-layer 130 can be deposited adjacent to transparent conductive oxide layer stack 120. Semiconductor window layer 131 can include any suitable window material, such as cadmium sulfide, and can be deposited by any suitable deposition method, such as sputtering or vapor transport deposition. Semiconductor absorber layer 132 can be deposited adjacent to semiconductor window layer 131. Semiconductor absorber layer 132 can be deposited on semiconductor window layer 131. Semiconductor absorber layer 132 can be any suitable absorber material, such as cadmium telluride, and can be deposited by any suitable method, such as sputtering or vapor transport deposition. Back contact 140 can be deposited adjacent to semiconductor absorber layer 132. Back contact 140 can be deposited adjacent to semiconductor bi-layer 130. A back support 150 can be positioned adjacent to back contact 140. A photovoltaic device can have a cadmium sulfide (e.g., CdS) layer as a semiconductor window layer and a cadmium telluride (e.g., CdTe) layer as a semiconductor absorber layer.

A buffer layer can be deposited between the TCO layer and the semiconductor window layer. The buffer layer can be used to decrease the likelihood of irregularities occurring during the formation of the semiconductor window layer. Additionally, a barrier layer can be incorporated between the substrate and the TCO layer to lessen diffusion of sodium or other contaminants from the substrate to the semiconductor layers, which could result in degradation and delamination. The barrier layer can be transparent, thermally stable, with a reduced number of pin holes and having high sodium-blocking capability, and good adhesive properties. Therefore the TCO can be part of a three-layer stack, which may include a barrier layer, a TCO layer, and a buffer layer. For example, the three-layer stack can include a silicon dioxide barrier layer, a cadmium oxide TCO layer, and a tin oxide buffer layer. The barrier layer can also include various suitable materials such as aluminum-doped silicon oxide, boron-doped silicon oxide and phosphorous-doped silicon oxide. The TCO layer can also include various suitable materials such as cadmium stannate, indium tin oxide and cadmium indium oxide. The buffer layer can also include various suitable materials, including tin oxide, zinc tin oxide, zinc oxide, or zinc magnesium oxide.

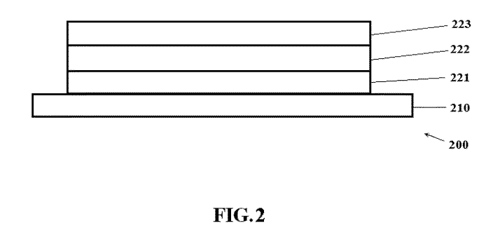

Referring to FIG. 2, photovoltaic substrate 200 can include transparent conductive oxide (TCO) stack 220 deposited adjacent to substrate 210. Substrate 210 can include a glass, such as soda-lime glass or an improved soda-lime glass with reduced iron content. Transparent conductive oxide stack 220 can be deposited on substrate 210 by sputtering, chemical vapor deposition, or any other suitable deposition method. In certain embodiments, transparent conductive oxide stack 220 can be deposited by reactive sputtering with O₂/Ar gas flow. Transparent conductive oxide stack 220 can include barrier layer 221, transparent conductive oxide layer 222, and buffer layer 223. Barrier layer 221 can be deposited or formed adjacent to substrate 210. Transparent conductive oxide layer 222 can be deposited or formed adjacent to barrier layer 221. Buffer layer 223 can be deposited or formed adjacent to transparent conductive oxide layer. TCO stack 220 can transform to conducting/transparent state during the following semiconductor layers deposition process, thus no additional annealing process is needed.

TCO layers with high optical transmission, high electrical conductivity and good light scattering properties are always desirable. For a TCO layer made of pure tin oxide, its thickness sheet resistance can be lowered (for example to about 5 ohms/square) by increasing layer thickness. In practice, the thick TCO layer can result in cost increase. Cracks can also appear in thick TCO films, leading to peeling and adhesion problems. Furthermore, very thick TCO films can create supplementary difficulties while patterning the TCO during the production step of series connection for module production.

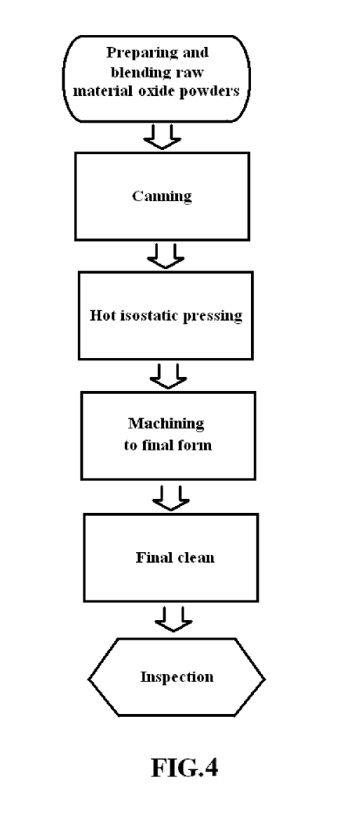

TCO layer can be doped to reduce the resistivity and promote the mobility of solar cell front contacts without increasing its thickness. Methods of making doped TCO layer can include a sputter process from a doped target. Referring to FIG. 4, making a doped sputter target can include the steps of preparing and blending raw material oxide powders, canning the powders, hot isostatic pressing the powders, machining to final form, final clean, and inspection. Making a doped sputter target can further include annealing or any other suitable metallurgy technique or other treatment. Oxide powders can include cadmium oxide and indium oxide. The doped sputter target can include about 2.2, 5.4, or 10.8 weight percentage of indium oxide. In other embodiments, the doped sputter target can also include other suitable oxide such as tin oxide or tin oxide with at least one dopant such as boron, sodium, fluorine, or aluminum.

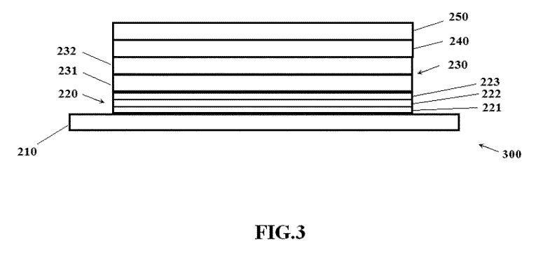

Referring to FIG. 3, photovoltaic device 300 can include transparent conductive oxide (TCO) stack 220 deposited adjacent to substrate 210. Substrate 210 can include a glass, such as soda-lime glass or an improved soda-lime glass with reduced iron content. Transparent conductive oxide stack 220 can be deposited on substrate 210 by sputtering, chemical vapor deposition, or any other suitable deposition method. In certain embodiments, transparent conductive oxide stack 220 can be deposited by reactive sputtering with O₂/Ar gas flow. Transparent conductive oxide stack 220 can include barrier layer 221, transparent conductive oxide layer 222, and buffer layer 223. Barrier layer 221 can be deposited or formed adjacent to substrate 210. Transparent conductive oxide layer 222 can be deposited or formed adjacent to barrier layer 221. Buffer layer 223 can be deposited or formed adjacent to transparent conductive oxide layer.

TCO stack 220 can also be manufactured using a variety of deposition techniques, including for example, low pressure chemical vapor deposition, atmospheric pressure chemical vapor deposition, plasma-enhanced chemical vapor deposition, thermal chemical vapor deposition, DC or AC sputtering, spin-on deposition, and spray-pyrolysis. Each deposition layer can be of any suitable thickness in the range of about 1 to about 5000 angstrom. For example, the thicknesses of barrier layer 221, transparent conductive oxide layer 222, and buffer layer 223 can be in the range of about 1000 angstrom to about 2500 angstrom respectively. Barrier layer 221 can include silicon oxide. Transparent conductive oxide layer 222 can include cadmium oxide and indium oxide (CdO:(In₂O₃)ₓ, wherein x can be in the range of about 0.05 to about 0.5. Buffer layer 223 can include tin oxide. Transparent conductive oxide layer 222 can also include any suitable transparent conductive oxide material, including a cadmium stannate or a tin-doped indium oxide. TCO stack 220 can transform to conducting/transparent state during the following semiconductor layers deposition process, thus no additional annealing process is needed.

Semiconductor bi-layer 230 can be formed or deposited adjacent to transparent conductive oxide stack 220. Semiconductor bi-layer 230 can include semiconductor window layer 231 and semiconductor absorber layer 232. Semiconductor window layer 231 of semiconductor bi-layer 230 can be deposited adjacent to transparent conductive oxide stack 220. Semiconductor window layer 231 can include any suitable window material, such as cadmium sulfide, and can be deposited by any suitable deposition method, such as sputtering or vapor transport deposition. Semiconductor absorber layer 232 can be deposited adjacent to semiconductor window layer 231. Semiconductor absorber layer 232 can be deposited on semiconductor window layer 231. Semiconductor absorber layer 232 can be any suitable absorber material, such as cadmium telluride, and can be deposited by any suitable method, such as sputtering or vapor transport deposition. Back contact 240 can be deposited adjacent to semiconductor absorber layer 232. Back contact 240 can be deposited adjacent to semiconductor bi-layer 230. A back support 250 can be positioned adjacent to back contact 240.

A sputtering target can be manufactured by ingot metallurgy. A sputtering target can include one or more components of a layer or film to be deposited or otherwise formed on a surface, such as a substrate. For example, a sputtering target can include one or more components of a TCO layer to be deposited on a substrate, such as zinc for a zinc oxide TCO layer, tin for a tin oxide TCO layer, or a dopant such as a N-type dopant, including boron, sodium, fluorine, or aluminum. The components can be present in the target in stoichiometrically proper amounts. A sputtering target can be manufactured as a single piece in any suitable shape. A sputtering target can be a tube. A sputtering target can be manufactured by casting a metallic material into any suitable shape, such as a tube.

A sputtering target can be manufactured from more than one piece. A sputtering target can be manufactured from more than one piece of metal, for example, a piece of zinc for a zinc oxide TCO and a piece of dopant material, such as aluminum. The components can be formed in any suitable shape, such as sleeves, and can be joined or connected in any suitable manner or configuration. For example, a piece of zinc and a piece of aluminum can be welded together to form the sputtering target. One sleeve can be positioned within another sleeve.

A sputtering target can be manufactured by powder metallurgy. A sputtering target can be formed by consolidating metallic powder to form the target. The metallic powder can be consolidated in any suitable process (e.g., pressing such as isostatic pressing) and in any suitable shape. The consolidating can occur at any suitable temperature. A sputtering target can be formed from metallic powder including more than one metal powder. More than one metallic powder can be present in stoichiometrically proper amounts.

A sputter target can be manufactured by positioning wire including target material adjacent to a base. For example wire including target material can be wrapped around a base tube. The wire can include multiple metals present in stoichiometrically proper amounts. The base tube can be formed from a material that will not be sputtered. The wire can be pressed (e.g., by isostatic pressing).

A sputter target can be manufactured by spraying a target material onto a base. Metallic target material can be sprayed by any suitable spraying process, including thermal spraying and plasma spraying. The metallic target material can include multiple metals, present in stoichiometrically proper amounts. The base onto which the metallic target material is sprayed can be a tube.

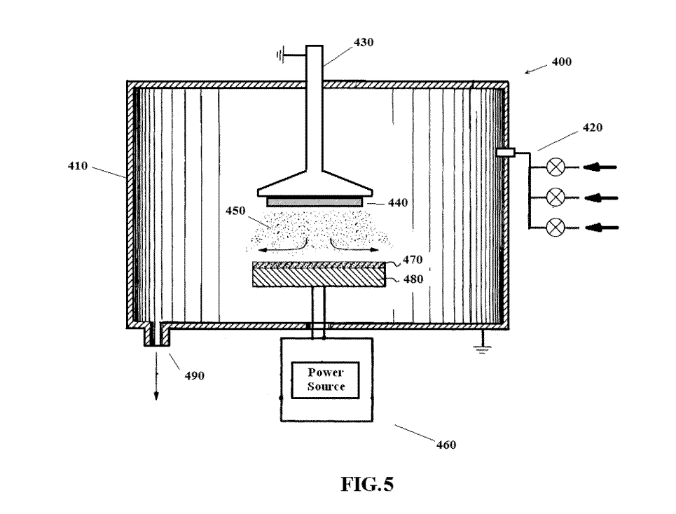

TCO stack can be deposited by sputtering. Referring to FIG. 5, sputter system 400 can include chamber 410. Sputter system 400 can be an AC sputtering system or DC sputtering system and include pulsed DC power supply 460 with a 4 microsecond pulse. The power output of the source can range from about 3 kW (˜1.4 W/cm²) to about 9 kW (˜4.2 W/cm²). The target voltage can range from about 300 volts to about 420 volts. Sputter system 400 can also be a RF sputtering system and include radio-frequency source and matching circuit. Substrate 470 can be mounted on plate 480 or positioned in any other suitable manner. The target-to-substrate distance can range from 50 mm to 500 mm. Grounded fixture 430 can hold doped sputter target 440 facing down. The gas in chamber 410 is taken from inlet 420 with sources of different gas. The gas in chamber 410 can include argon and oxygen. The pressure in chamber 410 can be within the range from about 2.0 mTorr to about 8.0 mTorr. During sputtering process, particles 450 can be deposited from target 440 to substrate 470.

The sputtering process can be a reactive sputtering process. The deposited transparent conductive oxide film can be formed by chemical reaction between the target material and the gas which is introduced into the vacuum chamber. The composition of the film can be controlled by varying the relative pressures or gas flow rates of the inert and reactive gases in chamber 410. For example, the inert gas can be argon and the reactive gas can be oxygen. In other embodiments, the gas in chamber 410 can further include dopant gas containing boron, sodium, fluorine, or aluminum. System 400 can include outlet 490 to exhaust gas. In other embodiments, the sputtering process can be a magnetron sputter deposition, or ion assisted deposition.

Referring to FIG. 5, deposition and processing TCO stack can also include the steps of substrate wash/rinse, sputter deposition, and coating or any other suitable post-process step. The process can include a heat treatment or any suitable drive-in treatment after wash. The process can also include an additional diffusion doping process with impurity ions in gaseous form. The methods of making doped TCO layer can also include an additional step of annealing the substrate after the doped transparent conductive oxide layer is deposited.

For example, TCO stack (220 in FIG. 2) can be deposited by separate reactive sputtering processes. Barrier layer (221 in FIG. 2) can be deposited adjacent to substrate (210 in FIG. 2) by reactive sputtering from an aluminum-doped Si target. The thickness of the barrier layer can range from about 250 angstrom to about 2500 angstrom. Transparent conductive oxide layer (222 in FIG. 2) can be deposited adjacent to barrier layer by reactive sputtering from, for example, a CdO: 5.4% In₂O₃ target by weight percentage. The O₂/Ar gas flow ratio can be from about 5% to about 50% O₂ in Ar. The thickness of the transparent conductive oxide layer can range from about 1000 angstrom to about 4000 angstrom. Buffer layer (223 in FIG. 2) can be deposited adjacent to transparent conductive oxide layer by reactive sputtering from a tin metal target. The O₂/Ar gas flow ratio can be from about 25% to about 50% O₂ in Ar. The thickness of the buffer layer can range from about 250 angstrom to about 2500 angstrom.

In a subsequent experiment, an additional post-annealing process can be included. The length of the annealing process can range from about 10 min to 30 min. The temperature of the annealing process can range from about 400 degree C. to 600 degree C. The annealing process can be a nitrogen annealing or vacuum annealing. The TCO stack demonstrates desirable resistivity (less than 1.0×10⁻⁴ ohm·cm), carrier concentration (about 7.0×10²⁰ cm⁻³), carrier mobility (about 90 cm²/V·s), and average visible range absorption (less than 10%). The sheet resistance can be in the range below 4 ohms/square.

The transparent conductive oxide layer can also be doped with a dopant, such as titanium, gallium, tin, yttrium, scandium, niobium, or molybdenum.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A photovoltaic substrate comprising:
a substrate;
a barrier layer adjacent to the substrate;
a transparent conductive oxide layer adjacent to the barrier layer, wherein the transparent conductive oxide layer can be doped with a dopant to achieve lower resistivity; and
a buffer layer adjacent to the transparent conductive oxide layer.

2. The photovoltaic substrate of claim 1, wherein the transparent conductive oxide layer comprises cadmium oxide.

3. The photovoltaic substrate of claim 1, wherein the transparent conductive oxide layer comprises indium oxide.

4. The photovoltaic substrate of claim 1, wherein the transparent conductive oxide layer comprises cadmium indium oxide.

5. The photovoltaic substrate of claim 1, wherein the dopant comprises titanium.

6. The photovoltaic substrate of claim 1, wherein the dopant comprises gallium.

7. The photovoltaic substrate of claim 1, wherein the dopant comprises tin.

8. The photovoltaic substrate of claim 1, wherein the dopant comprises yttrium.

9. The photovoltaic substrate of claim 1, wherein the dopant comprises scandium.

10. The photovoltaic substrate of claim 1, wherein the dopant comprises niobium.

11. The photovoltaic substrate of claim 1, wherein the dopant comprises molybdenum.

12. The photovoltaic substrate of claim 1, wherein the buffer layer comprises tin oxide.

13. The photovoltaic substrate of claim 1, wherein the buffer layer comprises zinc oxide.

14. The photovoltaic substrate of claim 1, wherein the buffer layer comprises zinc tin oxide.

15. The photovoltaic substrate of claim 1, wherein the transparent conductive oxide layer can be doped with a dopant to control the band gap.

16. The photovoltaic substrate of claim 1, wherein the substrate comprises glass.

17. The photovoltaic substrate of claim 1, further comprising:
a semiconductor bi-layer adjacent to the transparent conductive oxide layer, wherein the semiconductor bi-layer comprises a semiconductor absorber layer and a semiconductor window layer.

18. The photovoltaic substrate of claim 1, wherein the barrier layer comprises silicon oxide.

19. A photovoltaic device comprising:
a substrate;
a barrier layer adjacent to the substrate;
a transparent conductive oxide layer adjacent to the barrier layer, wherein the transparent conductive oxide layer can be doped with a dopant to achieve lower resistivity;
a buffer layer adjacent to the transparent conductive oxide layer; and
a semiconductor bi-layer adjacent to the transparent conductive oxide layer, wherein the semiconductor bi-layer comprises a semiconductor absorber layer and a semiconductor window layer.

20. The photovoltaic device of claim 19, wherein the transparent conductive oxide layer comprises cadmium oxide, indium oxide, or cadmium indium oxide.

21. The photovoltaic device of claim 19, wherein the dopant comprises titanium, gallium, tin, yttrium, scandium, niobium, or molybdenum.

22. The photovoltaic device of claim 19, wherein the buffer layer comprises tin oxide, zinc oxide, or zinc tin oxide.

23. The photovoltaic device of claim 19, wherein the transparent conductive oxide layer can be doped with a dopant to control the band gap.

24. The photovoltaic device of claim 19, wherein the substrate comprises glass.

25. The photovoltaic device of claim 19, wherein the semiconductor absorber layer comprises cadmium telluride.

26. The photovoltaic device of claim 19, wherein the semiconductor window layer comprises cadmium sulfide.

27. The photovoltaic device of claim 19, wherein the barrier layer comprises silicon oxide.

28. The photovoltaic device of claim 19, wherein the thicknesses of the barrier layer can be in the range of about 250 angstrom to about 2500 angstrom.

29. The photovoltaic device of claim 19, wherein the thicknesses of the transparent conductive oxide layer can be in the range of about 1000 angstrom to about 4000 angstrom.

30. The photovoltaic device of claim 19, wherein the thicknesses of the buffer layer can be in the range of about 250 angstrom to about 2500 angstrom.

31. A method of manufacturing a photovoltaic substrate comprising the steps of:
depositing a barrier layer adjacent to a substrate;
depositing a transparent conductive oxide layer adjacent to the barrier layer, wherein the transparent conductive oxide layer can be doped with a dopant to achieve lower resistivity;
depositing a buffer layer adjacent to the transparent conductive oxide layer; and
depositing a semiconductor bi-layer adjacent to the buffer layer, wherein the semiconductor bi-layer comprises a semiconductor absorber layer and a semiconductor window layer.

32. The method of claim 31, wherein the transparent conductive oxide layer comprises cadmium oxide, indium oxide, or cadmium indium oxide.

33. The method of claim 31, wherein the dopant comprises titanium, gallium, tin, yttrium, scandium, niobium, or molybdenum.

34. The method of claim 31, wherein the buffer layer comprises tin oxide, zinc oxide or zinc tin oxide.

35. The method of claim 31, wherein the transparent conductive oxide layer can be doped with a dopant to control the band gap.

36. The method of claim 31, wherein the substrate comprises glass.

37. The method of claim 31, wherein the semiconductor absorber layer comprises cadmium telluride.

38. The method of claim 31, wherein the semiconductor window layer comprises cadmium sulfide.

39. The method of claim 31, wherein the barrier layer comprises silicon oxide.

40. The method of claim 31, wherein depositing the barrier layer comprises sputtering, or reactive sputtering.

41. The method of claim 31, wherein depositing the transparent conductive oxide layer comprises sputtering or reactive sputtering from a doped target.

42. The method of claim 31, wherein depositing buffer layer comprises sputtering.

43. The method of claim 31, wherein depositing the buffer layer comprises reactive sputtering.

44. The method of claim 31, further comprising annealing the transparent conductive oxide layer.

45. The method of claim 31, wherein the thicknesses of the barrier layer can be in the range of about 250 angstrom to about 2500 angstrom.

46. The method of claim 31, wherein the thicknesses of the transparent conductive oxide layer can be in the range of about 1000 angstrom to about 4000 angstrom.

47. The method of claim 31, wherein the thicknesses of the buffer layer can be in the range of about 250 angstrom to about 2500 angstrom.
